(19) United States
(12) Patent Application Publication
(10) Pub. No.: US 2008/0305576 A1
(43) Pub. Date: Dec. 11, 2008

(54) METHOD OF REDUCING WARPAGE IN SEMICONDUCTOR MOLDED PANEL

(76) Inventors: Cheemen Yu, Madison, WI (US); Chih-Chin Liao, Yuanlin (TW); Hem Takiar, Fremont, CA (US)

Correspondence Address: VIERRA MAGEN/SANDISK CORPORATION, 575 MARKET STREET, SUITE 2500, SAN FRANCISCO, CA, 94105, US

(21) Appl. No.: 11/759,475

(22) Filed: Jun. 7, 2007

(51) Int. Cl. H01L 21/02

(52) U.S. Cl. 438/107; 257/E23.003

(57) ABSTRACT

A panel is disclosed on which a plurality of integrated circuit package outlines may be fabricated within a plurality of process tools. The panel includes recessed portions in the exposed surfaces of the molding compound and/or the substrate. The recesses relieve stress resulting from disparate coefficients of expansion between the substrate and molding compound applied to the substrate around the integrated circuits. In embodiments, the recesses may be formed as lines scored into the surface of the molding compound or substrate. Alternatively, the recesses may be formed in the solder mask on the substrate during a process for applying the solder mask, or the recesses may be formed in the molding compound during the encapsulation process.

### CROSS-REFERENCE TO RELATED APPLICATION

The following application is cross-referenced and incorporated by reference herein in its entirety:

U.S. patent application Ser. No. ______ [Attorney Docket No. SAND-01248US1], entitled “Semiconductor Molded Panel Having Reduced Warpage,” by Cheemen Yu, et al., filed on even date herewith.

### BACKGROUND OF THE INVENTION

1. Field of the Invention

Embodiments of the present invention relate to panels for integrated circuit package outlines, the panels having a maximized usable area.

2. Description of the Related Art

The strong growth in demand for portable consumer electronics is driving the need for high-capacity storage devices. Non-volatile semiconductor memory devices, such as flash memory storage cards, are becoming widely used to meet the ever-growing demands on digital information storage and exchange. Their portability, versatility and rugged design, along with their high reliability and large capacity, have made such memory devices ideal for use in a wide variety of electronic devices, including for example digital cameras, digital music players, video game consoles, PDAs and cellular telephones.

While a number of packaging configurations are known, flash memory storage cards may in general be fabricated as system-in-a-package (SiP) or multichip modules (MCM), where a plurality of die are mounted on a substrate. The substrate may in general include a rigid base having a conductive layer etched on one or both sides. Electrical connections are formed between the die and the conductive layer(s), and the conductive layer(s) provide an electric lead structure for integration of the die into an electronic system. Once electrical connections between the die and substrate are made, one or both sides of the assembly are then typically encased in a molding compound to provide a protective package outline.

Significant economies of scale are achieved by forming a plurality of integrated circuit (IC) die package outlines at the same time on panels. Once fabricated, the IC die packages are separated from the panel, and those which pass inspection may then form a completed flash memory card, or be enclosed within an outer plastic cover to form a completed flash memory card. A conventional IC package panel 20 is shown in top view in prior art FIG. 1. Panel 20 includes a substrate 22 on which are formed a plurality of IC die packages within respective IC die package outlines 24. In the view of FIG. 1, the integrated circuits have been formed on the substrate 22, and have been encapsulated in a molding compound 26.

In order to orient the panel 20 and register a position of the panel within process tools for fabricating the finished chip packages, the panel 20 traditionally includes a plurality of fiducial holes 28 at the periphery of the panel 20. In particular, when a panel is transferred into a process tool, such as for example a die bond tool, the panel is moved along the x-direction (with respect to the x-y coordinate system indicated in FIG. 1) until an optical recognition sensor registers the position of a first fiducial hole 28a of the fiducial holes 28. The optical recognition sensor may for example include a transmitter on one side of the panel emitting a beam to a receiver on the opposite side of the panel. When the hole is aligned with the optical sensor, the beam passes through the hole and is received within the receiver to register the position of the panel. Once a position of the panel is identified along the x-axis, the tool indexes the panel along the y-axis to process all IC package outlines within a given column.

Once a column is completed, the panel 20 is indexed back to the starting y-axis position, and then moved along the x-axis until the next fiducial hole, e.g., hole 28b registers with the optical sensor. This process is continued until the IC package outlines 24 in each row and column have been processed within the tool. The panel may then be transferred to the next assembly tool in the fabrication process and the fiducial holes 28 are again used to register a position of the panel with respect to equipment within the tool. Other fabrication schemes using fiducial holes 28 are known.

Owing to differences in the coefficients of thermal expansion between the substrate 22 and the molding compound 26 encapsulating the integrated circuits on the panel 20, the panel 20 may warp during the fabrication process. In particular, the molding compound 26 is applied to the substrate at elevated temperatures. When the panel 20 cools, the substrate and/or molding compound may shrink different amounts. Thus, where the substrate 22 shrinks to a greater degree than the molding compound 26, the panel 20 may warp so that the ends curve downward as shown in prior art FIG. 2. Conversely, where the molding compound shrinks to a greater degree than the substrate, the panel 20 may warp so that the ends curve upward as shown in prior art FIG. 3. Warping of the panel 20 during the fabrication process may cause an edge of the panel to catch on a process tool and get stuck. This adds significant time and expense to the fabrication process, as the particular process must be stopped, and offending panel manually righted or removed.

### SUMMARY OF THE INVENTION

Embodiments of the present invention relate to a panel on which a plurality of integrated circuit packages may be fabricated within a plurality of process tools. The panel includes recessed portions in the exposed surfaces of the molding compound and/or the substrate. The recesses relieve stress resulting from disparate coefficients of expansion between the substrate and molding compound applied to the substrate around the integrated circuits. In embodiments, the recesses may be formed as lines scored into the surface of the molding compound or substrate. Alternatively, the recesses may be formed in the solder mask on the substrate during a process for applying the solder mask, or the recesses may be formed in the molding compound during the encapsulation process.

In embodiments, the recesses are formed in either the molding compound or in the substrate. However, in a further embodiment of the present invention, the recesses may be formed in both the molding compound and the substrate, either across the width, along the length, or both. The recesses may be formed along each boundary between adjacent IC die package outlines. However, the recesses may be formed between less than each IC die package outline in alternative embodiments.

### BRIEF DESCRIPTION OF THE DRAWINGS

FIG. 1 is a top view of a prior art panel including a plurality of integrated circuit package outlines.

FIG. 2 is a side view of the prior art panel of FIG. 1 warped downward.

FIG. 3 is a side view of the prior art panel of FIG. 1 warped upward.

FIG. 4 is a top view of a panel including recesses in a molding compound on the panel according to an embodiment of the present invention.

FIG. 5 is a side view of the panel shown in FIG. 4.

FIG. 6 is a bottom view of a panel including recesses in a substrate of the panel according to an embodiment of the present invention.

FIG. 7 is side a view of the panel shown in FIG. 6.

FIG. 8 is a side view of a semiconductor package formed from a panel according to the present invention.

FIG. 9 is a flow chart of a process for fabricating integrated circuit packages on a panel according to the present invention.

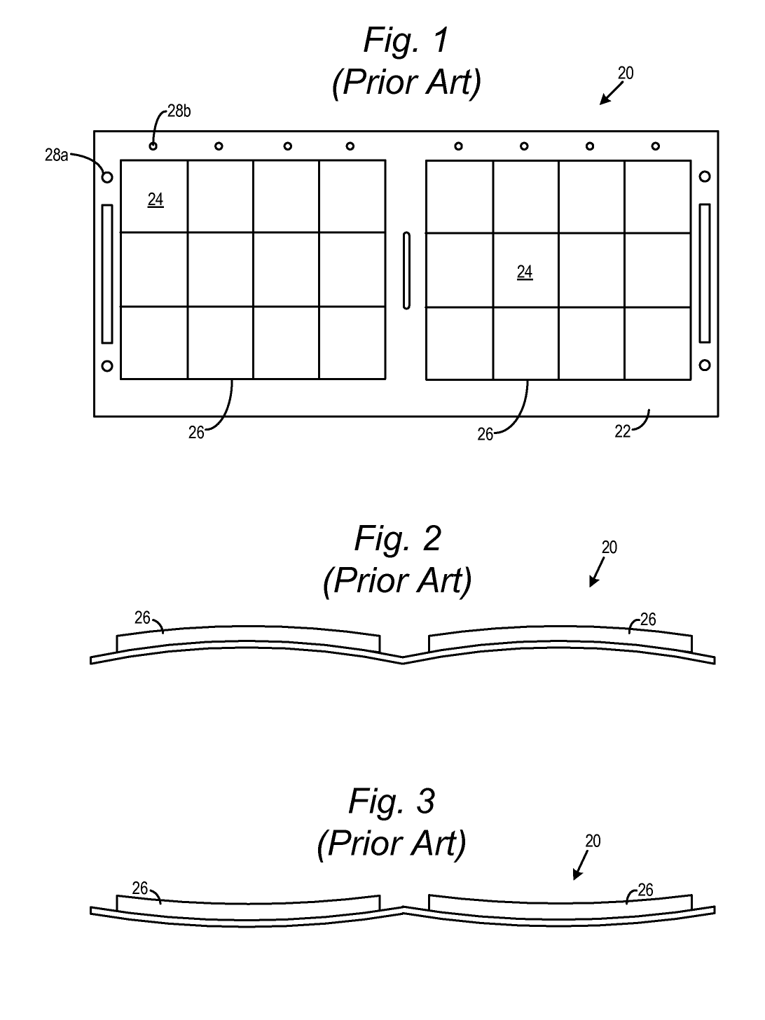

### DETAILED DESCRIPTION

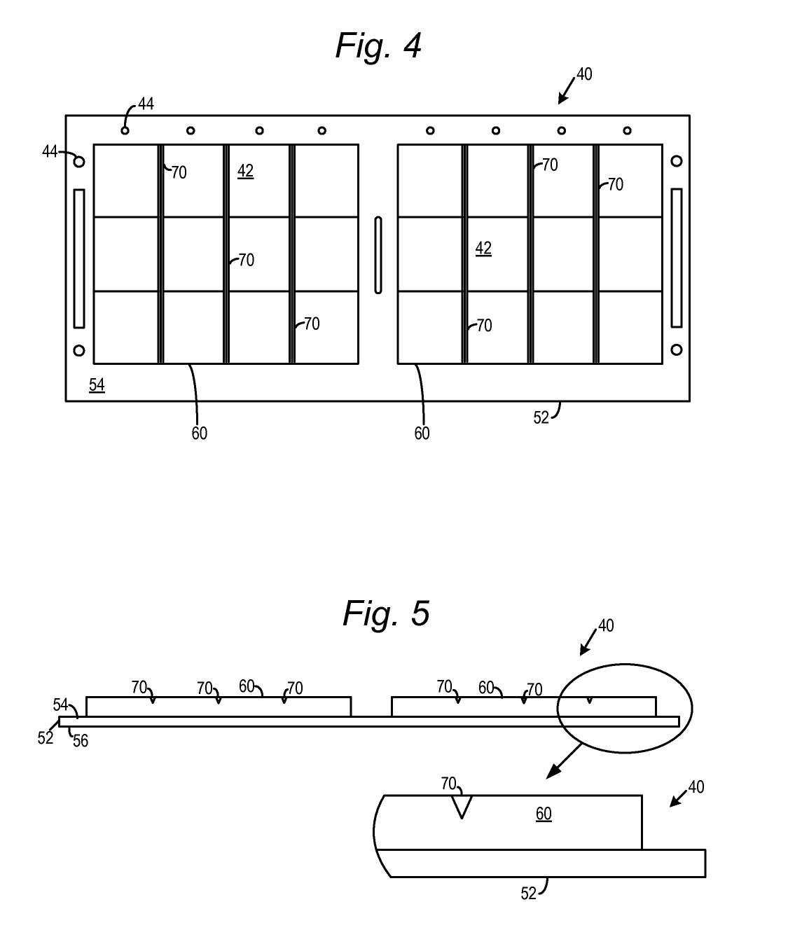

Embodiments of the invention will now be described with reference to FIGS. 4 through 9 which relate to panels for integrated circuit packages having reduced warping. It is understood that the present invention may be embodied in many different forms and should not be construed as being limited to the embodiments set forth herein. Rather, these embodiments are provided so that this disclosure will be thorough and complete and will fully convey the invention to those skilled in the art. Indeed, the invention is intended to cover alternatives, modifications and equivalents of these embodiments, which are included within the scope and spirit of the invention as defined by the appended claims. Furthermore, in the following detailed description of the present invention, numerous specific details are set forth in order to provide a thorough understanding of the present invention. However, it will be clear to those of ordinary skill in the art that the present invention may be practiced without such specific details.

Referring now to FIG. 4, there is shown a panel 40 including a plurality of IC package outlines 42 (only some of which are numbered in the figure). The panel 40 is shown prior to encapsulation. During the fabrication process, each package outline 42 will receive one or more semiconductor die and passive components as explained hereinafter. The panel 40 shown in the figures includes two groups of twelve IC package outlines 42. It is understood that the number of groups and the number of IC package outlines 42 within a group may vary in alternative embodiments of the invention. In embodiments, there may be a single group of IC package outlines 42. In one embodiment, the IC packages formed on panel 40 may be an LGA package for flash memory cards. It is understood that the IC package outline 42 may be for other types of semiconductor packages, including but not limited to for example BGA packages.

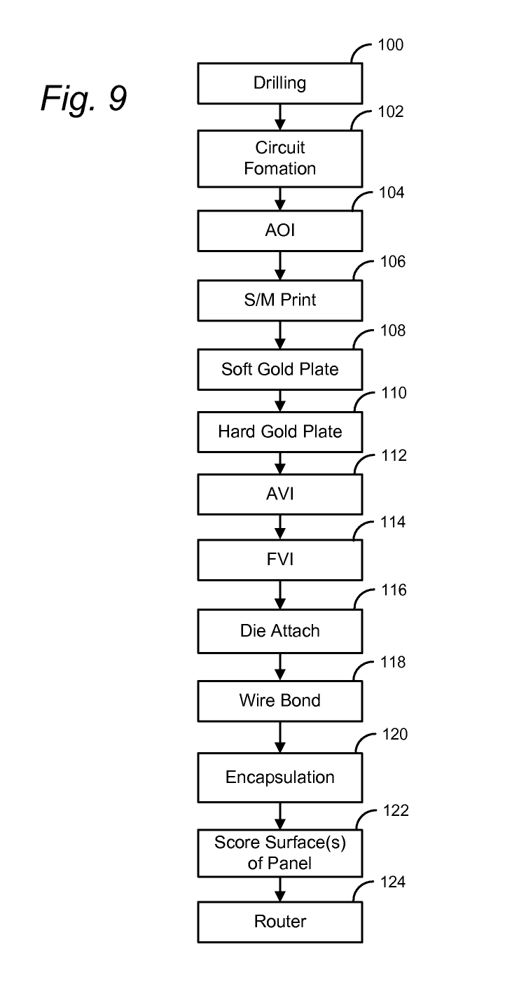

A process for forming the panel 40, and IC die packages therefrom, will now be described with reference to the flowchart of FIG. 9. Panel 40 begins with a substrate 52, having a top surface 54 and a bottom surface 56. Substrate 52 may be formed of a core, having a top conductive layer formed on a top surface of the core, and a bottom conductive layer formed on the bottom surface of the core. The core may be formed of various dielectric materials such as for example, polyimide laminates, epoxy resins including FR4 and FR5, bismaleimide triazine (BT), and the like. Although not critical to the present invention, the core may have a thickness of between 40 microns (μm) to 200 μm, although the thickness of the core may vary outside of that range in alternative embodiments. The core may be ceramic or organic in alternative embodiments.

The conductive layers on surfaces 54 and/or 56 of the substrate 52 may be formed of copper or copper alloys, plated copper or plated copper alloys, Alloy 42 (42Fe/58Ni), copper plated steel, or other metals and materials known for use on substrates. The conductive layers may have a thickness of about 10 μm to 24 μm, although the thickness of the conductive layers may vary outside of that range in alternative embodiments.

In step 100, fiducial holes (or notches) 44 may be drilled or otherwise formed through substrate 52 as seen for example in FIG. 4. The fiducial holes or notches 44 may be formed around the periphery of the panel 40 for registering the panel 40 within a process tool as is known in the art. In particular, the fiducial holes 44 may be used with a conventional optical recognition sensor within a process tool to register the position of the panel 40 during an IC package fabrication process. The panel 40 may be mounted on an X-Y table capable of translating the panel 40 in an X-direction parallel to a top edge of the panel 40, and in a Y-direction parallel to a side edge of the panel 40. The optical recognition sensor includes a transmitter for emitting a beam along an edge of the panel 40 as the panel 40 translates, and a receiver capable of receiving the beam when the beam is not blocked by the panel 40. Normally, the edge of the panel 40 prevents the beam from being received within the receiver. However, when the beam encounters a hole or notch 44, the beam passes through to the receiver to register a position of the panel 40.

In step 102, the conductive layers of the substrate 52 may be etched to form electrical conductance patterns on the upper and/or lower surfaces 54, 56 of the substrate in a known manner to provide electrical connections between components mounted on the substrate and a host device in which the finished packages are used. The conductance pattern(s) may be etched using for example known photolithography techniques. In embodiments including conductance patterns on both the top surface 54 and bottom surface 56, vias (not shown) may be provided to transmit electrical signals between the top and bottom surfaces of the substrate 52. The patterned panel may then be inspected in an automatic optical inspection (AOI) in step 104.

Once patterned and inspected, the top and bottom conductive layers may be laminated with a solder mask in step 106 as is known in the art. One or more gold layers (or other known plating material) may be formed on portions of the top and/or bottom conductive layers in areas to be soldered and in areas to define contact fingers for communication of the finished package with an external host device. It is known to apply a soft gold layer (step 108) and a hard gold layer (step 110) to the contact fingers to provide greater wear resistance. It is understood that only a single plating step may be employed.

The patterned substrate may then be inspected and tested in an automated step (step 112) and in a final visual inspection (step 114) to check electrical operation, and for contamination, scratches and discoloration. The panel 40 is then sent through the die attach process in step 116 to attach one or more semiconductor die to each package outline 42. The die are wire bonded to the plated pads on the substrate in a step 118. The die, wire bond and portions of the substrate are then encapsulated in step 120 with a molding compound 60 as shown in the figures. The encapsulation process may be a known injection mold process forming JEDEC standard (or other) package outlines on panel 40. Such molding compounds are available for example from Sumitomo Corp. and Nitto Denko Corp., both having headquarters in Japan. As described above, the package outlines 42 on panel 40 may be arranged in two groups as shown in the figures. The molding compound 60 may be applied as a continuous block encapsulating an entire group of packages on the panel 40.

As explained in the Background section, the encapsulation process applying molding compound to the blocks of package outlines on panel 40 takes place at elevated temperatures. Upon cooling, the panel 40 tends to warp given the disparate coefficients of thermal expansion between the molding compound 60 and the substrate 52. Accordingly, recessed portions 70 may be formed in the exposed surfaces of the molding compound and/or the substrate in step 122 and as shown in FIGS. 4 through 7. In embodiments, recesses 70 may be formed as lines scored into the surface of the molding compound or substrate. However, it is understood that the recesses 70 need not be lines in alternative embodiments. For example, the recesses could be a plurality of dots formed into the surface of the molding compound or substrate.

In embodiments, warping occurs along the length of the panel 40. That is, along the longer dimension of the panel as shown in prior art FIGS. 2 and 3, which is also the dimension along the path of travel of the panel 40 through process tools. Accordingly, recesses may be formed across the width of the molding compound or substrate as shown in the figures. However, it is understood that the recesses 70 may alternatively or additionally be formed along the length of the molding compound or substrate.

In embodiments explained below, the recesses 70 are formed in either the molding compound or in the substrate. However, in a further embodiment of the present invention, the recesses may be formed in both the molding compound and the substrate, either across the width, along the length, or both. Moreover, while the figures show the recesses 70 formed along the boundaries between each IC die package outline 42, it is understood that the recesses 70 may be formed between less than each IC die package outline 42 in alternative embodiments. Each group of package outlines 42 on panel 40 may include one or more recesses 70 for preventing warping of the substrate 52.

Referring initially to FIGS. 4 and 5, in one embodiment, recesses 70 may be formed down into the exposed surface of the molding compound 60. Recesses 70 may be lines scored into the surface of the molding compound 60 after step 120 of forming the molding compound. However, in an alternative embodiment, the recesses 70 may be formed during the encapsulation process. In particular, one of the mold plates defining the cavity within which the panel 40 is placed during the encapsulation process may include ridges which define the recesses 70 in the molding compound when the encapsulation process is finished. Where the recesses 70 are scored lines, the scored lines may be formed by blade (e.g., diamond saw), router or laser. As used herein, the term “score” means to cut into the surface by any of these methods.

The recesses may be formed to a depth of a few mils up to about a millimeter. The recesses may be formed to a lesser depth or a greater depth in alternative embodiments. Forming recesses in the molding compound as described with respect to FIGS. 4 and 5 prevents the panel from warping upward, such as for example shown in FIG. 3.

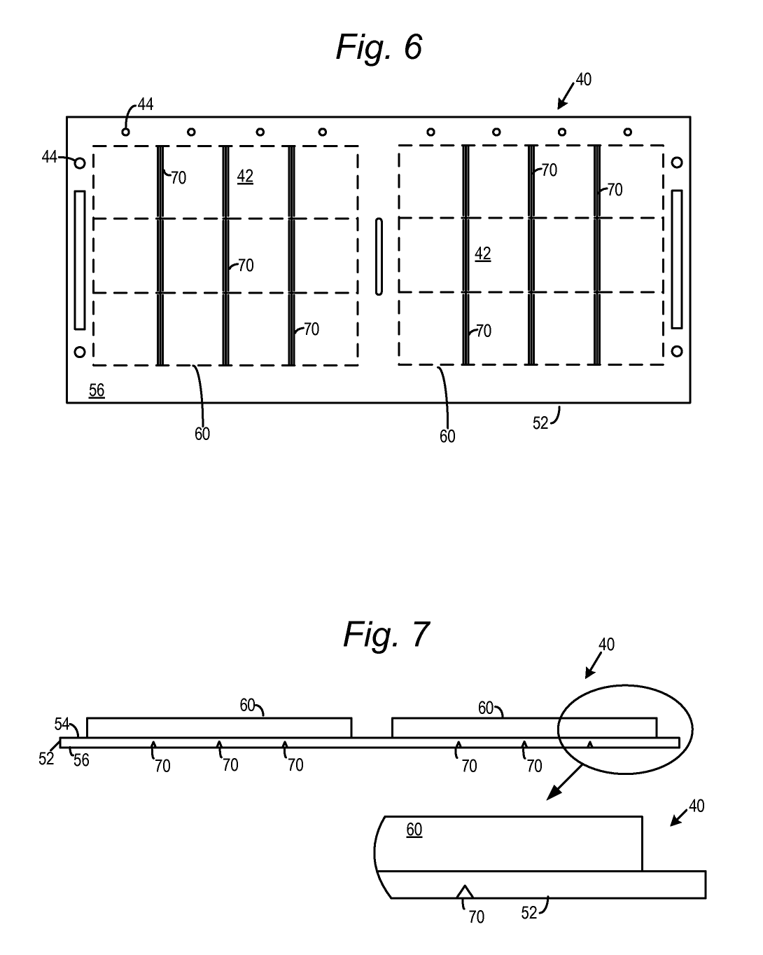

Referring now to FIGS. 6 and 7, in a further embodiment, recesses 70 may be formed into surface 56 of substrate 52. FIG. 6 is a view of the back side of the panel 40, showing surface 56 of substrate 52. In the embodiment of FIGS. 6 and 7, the recesses 70 may be formed in the solder mask printed onto the substrate in step 106. The lines may be scored into the surface of the solder mask after step 106 of printing the solder mask onto the substrate. However, in an alternative embodiment, the recesses 70 may be formed during the step of laminating the solder mask onto the substrate. In particular, a mask may be applied at the locations where the recesses 70 are to be formed in the solder mask. Once the solder mask is applied, the mask may be removed leaving the recesses in the solder mask. Where the recesses 70 are scored lines, the scored lines may be formed by blade (e.g., diamond saw), router or laser.

The recesses 70 may be formed to a depth of a few mils up to about a millimeter. The recesses 70 may be formed to a lesser depth or a greater depth in alternative embodiments. Forming recesses in the solder mask as described with respect to FIGS. 6 and 7 prevents the panel from warping downward, such as for example shown in FIG. 2. While the recesses preferably do not extend into the substrate beneath the solder mask, it is contemplated that the recesses 70 may be formed in at least portions of the substrate beneath the solder mask (without interfering or exposing any electrical traces of the conductance pattern).

After recesses 70 are formed in the panel 40 as described above, a router or other cutting device may then singulate the panel into individual IC packages in step 124. The singulated package may then be complete, or may further be encased within one or two plastic lids.

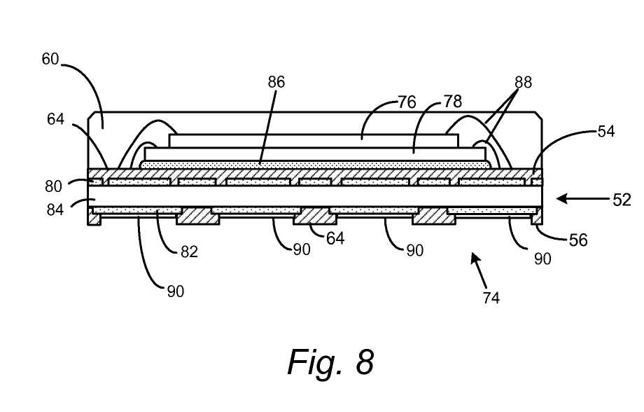

A semiconductor package 74 formed from panel 40 is shown in FIG. 8. The package 74 includes a pair of stacked semiconductor die 76, 78 mounted on the top surface 54 of the substrate 52. The substrate 52 may include conductive layers 80 and 82 formed on the dielectric core 84. Solder mask 64 may be applied to the top and bottom surfaces 54, 56 of the substrate 52. Instead of two semiconductor die, embodiments of the invention may alternatively include a single die, and embodiments of the invention may alternatively include between 3 and 8 or more die stacked in a SiP, MCM or other type of arrangement. The semiconductor die 76, 78 may be a memory chip and a controller chip, such as an ASIC. It is contemplated that the die 76, 78 may both be memory die, or may be other types of semiconductor die in further embodiments.

The die 78 may be mounted on the top surface 54 of the substrate 52 in a known adhesive or eutectic die bond process, using a known die attach compound 86. The one or more die 76, 78 may be electrically connected to conductive layers 80, 82 of the substrate 52 by wire bonds 88 in a known wire bond process.

In embodiments where the IC package 74 comprises an LGA package, the bottom surface 56 of substrate 52 may include contact fingers 90. The contact fingers 90 are provided to establish an electrical connection between the finished package 74 and contact pads of a host device (not shown) in a known manner when the contact fingers 90 are brought into pressure contact against the contact pads of the host device. While four contact fingers 90 are shown, it is understood that there may be more or less than four fingers in alternative configurations of the IC package 74. In an embodiment, there may be eight contact fingers. After the wire bond process is completed, IC package 74 may be encapsulated in molding compound 60.

The foregoing detailed description of the invention has been presented for purposes of illustration and description. It is not intended to be exhaustive or to limit the invention to the precise form disclosed. Many modifications and variations are possible in light of the above teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

We claim:

1. A method of fabricating integrated circuits on a panel, the method comprising the steps of:
(a) mounting one or more semiconductor on a substrate within each of a plurality of integrated circuit die package outlines;
(b) encapsulating the one or more semiconductor die mounted in said step (a) within a molding compound; and
(c) forming one or more recesses along a surface of one of the substrate and the molding compound to prevent warping of the panel.

2. A method as recited in claim 1, wherein said step (c) of forming one or more recesses along a surface of one of the substrate and the molding compound comprises the step of forming one or more recesses along a surface of one of the substrate and the molding compound along at least one border between adjacent package outlines.

3. A method as recited in claim 1, wherein said step (c) of forming one or more recesses along a surface of one of the substrate and the molding compound comprises the step of scoring one of the substrate and the molding compound.

4. A method as recited in claim 3, wherein said step of scoring a surface of one of the substrate and the molding compound comprises the step of scoring one of the substrate and molding compound with a cutting blade.

5. A method as recited in claim 3, wherein said step of scoring a surface of one of the substrate and the molding compound comprises the step of scoring one of the substrate and molding compound with a laser.

6. A method as recited in claim 1, further comprising the step of singulating integrated circuit die packages by cutting along the borders of the integrated circuit die package outlines.

7. A method as recited in claim 1, wherein said step (c) of forming one or more recesses along a surface of one of the substrate and the molding compound comprises the step of forming one or more recesses in the molding compound to prevent ends of the panel from warping upward.

8. A method as recited in claim 7, wherein said step of forming one or more recesses on the molding compound comprises the step of forming the one or more recesses during said step (b) of encapsulating the one or more semiconductor die.

9. A method as recited in claim 1, wherein said step (c) of forming one or more recesses along a surface of one of the substrate and the molding compound comprises the step of forming one or more recesses in the substrate to prevent ends of the panel from warping downward.

10. A method as recited in claim 9, wherein said step of forming one or more recesses along the substrate comprises the step of scoring a solder mask applied to a surface of the substrate.

11. A method as recited in claim 1, wherein said step (c) of forming one or more recesses along a surface of one of the substrate and the molding compound comprises the step of forming one or more recesses along one of the substrate and molding compound across a width of the panel.

12. A method as recited in claim 11, wherein said step of forming one or more recesses along one of the substrate and molding compound across a width of the panel comprises the step of forming one or more recesses along one of the substrate and molding compound between each adjacent integrated circuit die package outline.

13. A method as recited in claim 1, wherein said step (c) of forming one or more recesses along a surface of one of the substrate and the molding compound comprises the step of forming one or more recesses along one of the substrate and molding compound across a length of the panel.

14. A method as recited in claim 13, wherein said step of forming one or more recesses along one of the substrate and molding compound across a length of the panel comprises the step of forming one or more recesses along one of the substrate and molding compound between each adjacent integrated circuit die package outline.

15. A method as recited in claim 1, wherein said step (c) of forming one or more recesses along a surface of one of the substrate and the molding compound comprises the step of forming one or more recesses along one of the substrate and molding compound to a depth of between 1 mil and 1 mm.

16. A method of fabricating integrated circuits on a panel, the panel having a length oriented along the direction of travel of the panel through a process tool and a width transverse to and smaller than the length, the method comprising the steps of:
(a) mounting one or more semiconductor on a substrate within each of a plurality of integrated circuit die package outlines;
(b) encapsulating the one or more semiconductor die mounted in said step (a) within a molding compound; and
(c) scoring a surface of one of the substrate and the molding compound, along at least one border between adjacent package outlines across a width of the panel, to prevent warping of the panel.

17. A method as recited in claim 16, further comprising the step of singulating integrated circuit die packages by cutting along the borders of the integrated circuit die package outlines.

18. A method as recited in claim 16, wherein said step (c) of scoring a surface of one of the substrate and the molding compound comprises the step of scoring the molding compound to prevent ends of the panel from warping upward.

19. A method as recited in claim 16, wherein said step (c) of scoring a surface of one of the substrate and the molding compound comprises the step of scoring the substrate to prevent ends of the panel from warping downward.

20. A method as recited in claim 19, wherein said step of scoring the molding compound comprises the step of scoring a solder mask applied to a surface of the substrate.

21. A method as recited in claim 16, wherein said step of scoring one of the substrate and molding compound across a width of the panel comprises the step of scoring one of the substrate and the molding compound between each adjacent integrated circuit die package outline.

22. A method of fabricating integrated circuits on a panel, the panel having a length oriented along the direction of travel of the panel through a process tool and a width transverse to and smaller than the length, the method comprising the steps of:
(a) mounting one or more semiconductor on a substrate within each of a plurality of integrated circuit die package outlines;
(b) encapsulating the one or more semiconductor die mounted in said step (a) within a molding compound; and
(c) relieving stress tending to warp the panel along a length of the panel by cutting one or more recesses in a surface of one of the molding compound and substrate, along one or more borders between adjacent package outlines across a width of the panel.

23. A method as recited in claim 22, further comprising the step of singulating integrated circuit die packages by cutting along the borders of the integrated circuit die package outlines.

24. A method as recited in claim 22, wherein said step (c) of cutting one or more recesses in a surface of one of the molding compound and substrate comprises the step of scoring the molding compound to prevent ends of the panel from warping upward.

25. A method as recited in claim 22, wherein said step (c) of cutting one or more recesses in a surface of one of the molding compound and substrate comprises the step of scoring the substrate to prevent ends of the panel from warping downward.

26. A method as recited in claim 22, wherein said step (c) of cutting one or more recesses in a surface of one of the molding compound and substrate comprises the step of scoring one of the substrate and molding compound to a depth of 1 mil and 1 mm.
